(19) United States
(12) Patent Application Publication
(10) Pub. No.: US 2019/0071770 A1
(43) Pub. Date: Mar. 7, 2019

(54) Transparent Polymer With Glass-Like Properties

(71) Applicant: Methode Electronics Malta Ltd., Mriehel (MT)

(72) Inventors: Alexander Galea, Dingli (MT); Joseph Elias Khoury, Beirut (LB)

(21) Appl. No.: 16/109,249

(22) Filed: Aug. 22, 2018

(30) Foreign Application Priority Data
Sep. 5, 2017 (DE) 10 2017 120 423.7

(51) Int. Cl. C23C 16/40; C23C 16/56

(52) U.S. Cl. CPC C23C 16/402; C23C 16/56

(57) ABSTRACT

A method for manufacturing transparent polymer with glass-like properties involves depositing silica glass molecules on a substrate to be coated through a chemical vapor deposition process prior to completing a full curing process. The chemical vapor deposition process is performed within a vacuum or ‘quasi’ vacuum atmosphere, which is held at a temperature below 30° C. Upon completion of the chemical vapor deposition process, curing the coated substrate a second time at a temperature exceeding 150° C. A transparent polymer may be manufactured according to the method described.

### RELATED APPLICATION DATA

This application claims the benefit of German patent application Ser. No. DE 10 2017 120 423.7 filed on Sep. 5, 2017, currently pending, the disclosure of which is incorporated by reference herein.

### FIELD OF THE DISCLOSURE

The disclosure relates to a transparent polymer and a method for the manufacture of a transparent polymer with glass-like properties. In particular, in one aspect, the method includes (i) depositing silica glass molecules in the form of a chemical vapor deposition process prior to completing the full curing process, wherein the vapor deposition process is performed within a vacuum or ‘quasi’ vacuum atmosphere, which is held at a low temperature below 30° C., and (ii) upon completion of the deposition process, curing the silicone based product for a second time at a temperature exceeding 150° C.

### BACKGROUND

As weight reduction becomes an ever more important parameter in the transportation industry, the need for a glass-like but light-weight material becomes more apparent. Both glass and plastics have unique desirable properties which are sometimes contradictory to each other but both are required. Such properties include hard to scratch but tough to break, highly polished but non-reflective, cold feel but thermally insulating, light but sounding heavy, strain-free but thin. Such properties are normally found either in plastics only or in glass materials only but rarely in both.

Several attempts have been done in the past, e.g.: car windscreen is glass with a plastic lamination—hard and does not shatter but heavy, laptop screen is not reflecting but also not polished, etc.

A common material which exhibits more common properties between the two types of materials is silicone, which like glass is a derivative of silicon (Si) element. Silicones are considered a molecular hybrid between glass and organic linear polymers, they exhibit very low birefringence due to their low dn/dT, very easy to process in thin cross-sections with multiple curves and specific finishes that make them anti-reflective whilst highly polished, chemically stable and extremely tough. The only two properties that with current materials composition cannot be achieved is hardness and cold feel. Thus, it is desirable to achieve the properties of both glass and plastic polymers.

### SUMMARY

It is desirable to achieve a single product and/or material that through the combination of materials and processes is able to achieve the properties of both glass and plastic polymers as well as to conduct a corresponding method of manufacturing.

The solution to achieving the hardness and cold feel properties typically reserved for silica glass whilst preserving the properties of the optical quality flexible silicone is to deposit silica glass molecules in the form of a chemical vapor deposition process under a vacuum atmosphere prior to completing the full curing process which makes silicone chemically stable.

Chemical vapor deposition technique enables production of pure, uniform coatings of polymers, even on contoured surfaces. The chemical vapor deposition process preferably begins with tanks containing an initiator material and one or more monomers, which are the building blocks of the desired polymer coating. These are vaporized, either by heating them or reducing the pressure, and are then introduced into a vacuum chamber containing the material to be coated. The initiator helps to speed up the process in which the monomers link up in chains to form polymers on the surface of the substrate material.

The chemical vapor deposition process may include depositing a solid material from a gaseous phase onto a substrate by means of a chemical reaction. The deposition reaction involved is generally thermal decomposition, chemical oxidation, or chemical reduction. Chemical reactions occur on and near the hot surfaces, resulting in the deposition of a thin layer on the surface. In one example of thermal decomposition, silica glass compounds are transported to the substrate surface as a vapor and are reduced to the elemental polymer state on the substrate surface.

Thus, such a vapor deposition process is preferably performed within a vacuum or ‘quasi’ vacuum atmosphere which is held at a low temperature below 30° C., preferably below 20° C., and preferably higher than 5° C., in order to slow down significantly the completion of the silicone curing process enabling the chemical bonding of the hot silica glass vapor deposit to micron thickness dimensions. Upon completion of the deposition process, the silicone based product is cured for a second time at a temperature exceeding 150° C., preferably exceeding 180° C. in order to complete the stabilization process resulting in a material composite which has a light, soft and tough body with optically stable properties across a wide temperature range but with a smooth, highly polished and hard surface.

For the material to be achieved there are many variants of chemical vapor deposition-process which could be used. It is possible to use hot-wall reactors and cold-wall reactors, at sub-torr total pressures to above-atmospheric pressures, with and without carrier. There are also a variety of enhanced chemical vapor deposition processes, which involve the use of plasmas, ions, photons, lasers, hot filaments, or combustion reactions to increase deposition rates and/or lower deposition temperatures.

The hard surface can be equated to a kind of layer which is arranged on the flexible optical body of the final structure.

The process may not be restricted to a configuration of the structure having only one layer; the structure, may consist of a number of corresponding layers. The same applies with regard to the soft silicone, i.e. flexible optical body; also insofar a number of bodies may exist.

Although a material with soft properties like the soft silicone is used in this process the result comprises a material which is consists of a hard silica glass surface on the one side and a flexible optical body on the other side, the material being essentially one piece of material.

In the production process the flexible optical body, i.e. the softer part of the material, is the first part which will manufactured and achieved. The layer providing the hard surface is achieved in the manufacturing process with using the element that forms glass.

This product can be used for a wide range of applications such as the fascia for touch screens within the automotive harsh environment.

So the product achieved feels and “sounds” like glass, when the user is touching it; it feels cold like glass; it feels hard like glass. Nevertheless, the mechanical performance can be compared to that of silicone resp. rubber, i.e. it does not break easily, highly polished but non-reflective, thermally insulating, light but sounding heavy, strain free but thin. It also has good optical properties. Compared to “normal” glass the material is much lighter. It also has to certain extend “stretching” properties, which “normal” glass does not have.

### DESCRIPTION OF DRAWINGS

The embodiments of the disclosure are described in more detail on the basis of the following figures, without being restricted, however, to such a configuration, wherein:

FIG. 1 shows exemplary chemical structures of silica glass, resins silsesquixanes, and linear polymers;

FIG. 2 shows an exemplary structure achieved through the described process; and

FIG. 3 shows exemplary geometrical structures achieved by the described process.

### DETAILED DESCRIPTION

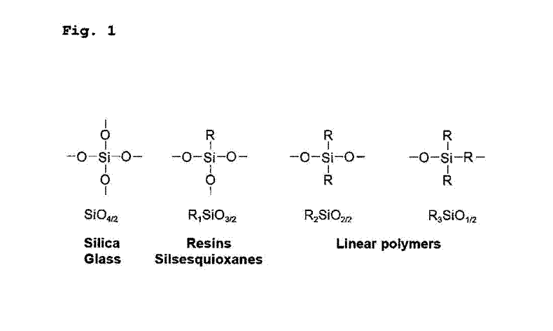

FIG. 1 discloses the chemical structure of silica glass, resins silsesquioxanes, linear polymers. The silica glass is the basis for the chemical vapor deposition process. Silicon-containing organic polymers in the present form of silsesquioxanes are used according to the present invention because of their potential replacement for, and compatibility with silicon-based inorganics in the present technology of the invention. Silsesquioxane materials used for the invention exhibit an enhancement in properties such as solubility, thermal and thermomechanical stability, mechanical toughness, optical transparency, gas permeability, dielectric constant, and fire retardancy.

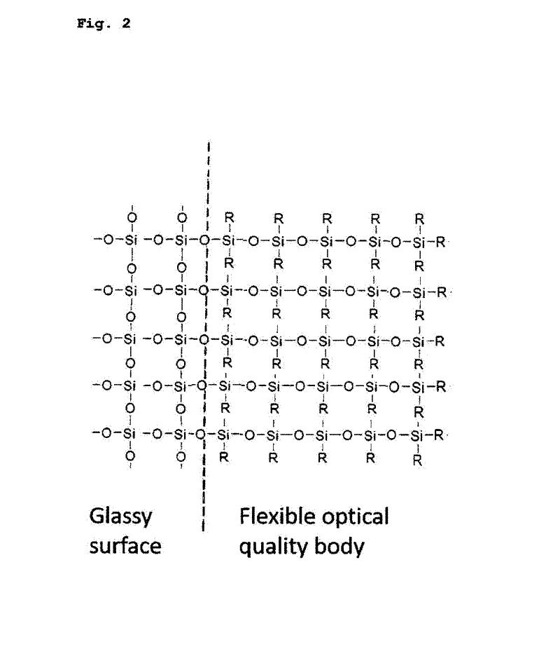

FIG. 2 shows the chemical structure achieved by the described process, wherein the part left to the dashed vertical dividing line refers to the glassy surface whereas the part right to the dashed vertical dividing line refers to the flexible optical quality body. It is obvious that the chemical structure shown may be present in a various number forming a polymer chain appropriate for the manufacture of the product to be achieved. Essentially, this is one piece of material. As already mentioned this diagram of the chemical structure does not mean that there would be one hard surface, i.e. one layer, only; there may be a number of layers arranged on the flexible optical body of the final structure.

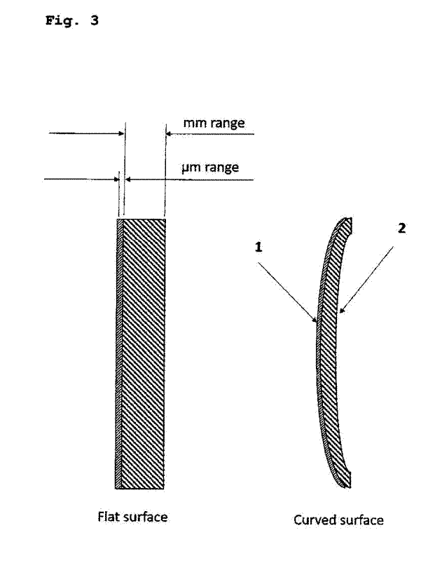

FIG. 3 shows examples of the geometry of a product achieved with the process of manufacturing, wherein 1 refers to the glassy surface and 2 refers to the tough, softer optical base material. Hence, the product achieved can have, for instance, a flat surface or a surface with single or multiple curve. The thickness of the glassy surface is in this example considerably thinner than the flexible optical quality body of the entire product. Accordingly, any geometrical configuration of the product can be achieved.

In view of the foregoing, it will be seen that the several advantages are achieved and attained. The embodiments were chosen and described in order to best explain the principles of the disclosure and their practical application to thereby enable others skilled in the art to best utilize the various embodiments and with various modifications as are suited to the particular use contemplated. As various modifications could be made in the constructions and methods herein described and illustrated without departing from the scope of the invention, it is intended that all matter contained in the foregoing description or shown in the accompanying drawings shall be interpreted as illustrative rather than limiting. Thus, the breadth and scope of the present invention should not be limited by any of the above-described exemplary embodiments, but should be defined only in accordance with the following claims appended hereto and their equivalents.

1. A method for manufacturing a transparent polymer with glass-like properties, the method comprising:
depositing silica glass molecules on a substrate to be coated through a chemical vapor deposition process prior to completing a full curing process, wherein the vapor deposition process is performed within a vacuum or ‘quasi’ vacuum atmosphere which is held at a temperature below 30° C.; and
upon completion of the chemical vapor deposition process, curing the coated substrate for a second time at a temperature exceeding 150° C.

2. A transparent polymer formed in accordance with the method of claim 1.
